(19) United States
(12) Patent Application Publication
(10) Pub. No.: US 2016/0099200 A1
(43) Pub. Date: Apr. 7, 2016

(54) ALUMINUM ALLOY LEAD FRAME FOR A SEMICONDUCTOR DEVICE AND CORRESPONDING MANUFACTURING PROCESS

(71) Applicant: STMICROELECTRONICS S.R.L., Agrate Brianza (IT)

(72) Inventors: Laura Ceriati, Carnate (IT); Paolo Crema, Vimercate (IT); Agatino Minotti, Mascalucia (IT)

(21) Appl. No.: 14/750,920

(22) Filed: Jun. 25, 2015

(30) Foreign Application Priority Data
Oct. 1, 2014 (IT) TO2014A000785

(51) Int. Cl. H01L 23/495; H01L 23/31; H01L 21/48; H01L 21/56; H01L 23/00

(52) U.S. Cl. CPC H01L 23/49582; H01L 21/56; H01L 24/85; H01L 21/4835; H01L 23/49503; H01L 23/49562; H01L 23/3107; H01L 24/49; H01L 24/83; H01L 24/73; H01L 24/32; H01L 2224/32245; H01L 2224/48106; H01L 2224/48245; H01L 2224/83801; H01L 2924/17724; H01L 2924/01012; H01L 2924/01014

(57) ABSTRACT

Described herein is a semiconductor device provided with: a die of semiconductor material; a lead frame, defining a support plate, which is designed to carry the die, and leads, which are designed to be electrically coupled to the die; and a package, of encapsulating material, which is designed to encapsulate the die and partially coming out of which are the leads. The lead frame has as constituent material an aluminum alloy comprising a percentage of silicon ranging between 1% and 1.5%.

### BACKGROUND

1. Technical Field

The present disclosure relates to an aluminum alloy lead frame for a semiconductor device, in particular a power semiconductor device; the present disclosure further relates to a corresponding manufacturing process.

2. Description of the Related Art

Known to the art are semiconductor devices, in particular of the power type, for example power MOSFETs, that comprise a plastic package designed to encapsulate a die including semiconductor material and integrating a corresponding integrated electronic component, where the plastic package is commonly obtained by molding.

For example, FIG. 1 shows a semiconductor device 1 (in particular, a power device) encapsulated in a package 2 of plastic material, for example epoxy resin.

The semiconductor device 1 comprises a die 3, including semiconductor material, in particular silicon, and a lead frame 4, which is arranged at least partially inside the package 2 and is designed to support the die 3 within the package 2 and to provide the electrical connection towards the outside of the integrated component present in the die 3.

The lead frame 4 comprises: a support plate, of metal material (generally known as “die pad” or “die paddle”) 5, which is arranged inside the package 2 and has a top surface 5a, coupled to which is the die 3, for example via interposition of a layer of adhesive material 6; and a plurality of leads 7, for example three in number, which come out of the package 2.

In a way here not illustrated, the die paddle 5 may be made of a single piece with one of the leads 7 (in particular with a lead arranged in a central position), thus constituting an electrode of the semiconductor device 1 (for example, the drain electrode of the power MOSFET). Further, the die 3 is electrically connected to the remaining leads 7 by electrical bond wires 8, which extend starting from respective contact pads, carried by a top surface of the die 3 not in contact with the die paddle 5, towards a respective lead 7 (the remaining leads being designed, for example, to define the source and gate electrodes of the power MOSFET).

The leads 7 of the lead frame 4 are then electrically coupled, for example by soldering, to corresponding electrical pads 9 carried by a top surface of a printed-circuit board (PCB) 10, of a known type and not described in detail herein.

Unlike what is illustrated in FIG. 1, the die paddle 5 may function as base of the package 2, being in this case arranged in contact with the external environment, at a bottom surface 5b thereof, opposite to the top surface 5a to which the die 3 is coupled, or else, as illustrated in the same FIG. 1, the die paddle 5 may be coated also underneath by a portion of the encapsulating material of the package 2.

In any case, the die paddle 5 may act also as a heat transfer element, for transferring heat generated in use by the component integrated in the die 3, towards an external heat dissipater (not illustrated).

Manufacturing of the semiconductor device 1 and of the corresponding lead frame 4, and of the electrical connection towards the outside, for example towards the printed-circuit board 10, thus utilizes provision of a plurality of distinct electrical connection interfaces in regard to the lead frame 4, namely:
the interface for connection between first ends 7a of the leads 7, internal to the package 2, and the electrical bond wires 8, which may, for example, provide coupling between copper (as a material constituting the leads 7), and aluminum, copper, or gold (as a material constituting the electrical bond wires 8);
the interface for connection between second ends 7b of the leads 7, external to the package 2, and respective electrical pads 9 on the printed-circuit board 10, which, for example, may provide coupling between copper (as a material constituting the leads 7), and gold (as a material constituting the electrical pads 9); and
the interface for connection between the die paddle 5 and the die 3, through the layer of adhesive material 6, which may, for example, provide coupling between copper (as a material constituting the die paddle 5), and a tin alloy, for example SAC or SnPb.

Given that some of the aforesaid combinations of materials are not compatible with each other, or in any case may not enable a desired quality to be achieved for the electrical coupling, one or more intermediate layers are used, for example metal coupling layers, which are in general formed by electrodeposition on one or more of the materials to be coupled, and in particular on the lead frame 4. This intermediate coupling metal layers may, for example, include zinc, nickel, copper, silver, or tin, or an appropriate combination of these or further materials.

For example, US 2013/0221507 A1 discloses manufacturing of an aluminum alloy lead frame, which utilizes, during the process of manufacture of a corresponding package and of a corresponding semiconductor device, formation of a number of metal layers by electrodeposition, over the metal layer constituting the lead frame.

However, the presence of the aforesaid intermediate coupling metal layers entails an increase in the complexity of the manufacturing process and of the corresponding semiconductor devices, and a corresponding increase in costs; further, in an evident manner, also the possibility of faults or intrinsic defectiveness in the resulting semiconductor device is increased.

### BRIEF SUMMARY

One or more embodiments of the present disclosure provide an aluminum alloy lead frame for a semiconductor device that may enable the aforementioned problems and disadvantages associated to the known solutions to be overcome, either totally or in part.

According to the present disclosure, a semiconductor device and a corresponding manufacturing process are consequently provided

One embodiment is directed to a semiconductor device that includes a die including semiconductor material and a lead frame. The lead frame includes a support plate, which supports the die. The lead frame further includes leads electrically coupled to the die. The lead frame is is an aluminum alloy including a percentage of silicon that is between 1% and 1.5%. A package that includes encapsulating material encapsulates the die. A portion of the leads protrude from the package.

### BRIEF DESCRIPTION OF THE SEVERAL VIEWS OF THE DRAWINGS

For a better understanding of the present disclosure, preferred embodiments thereof are now described, purely by way of non-limiting example and with reference to the attached drawings, wherein:

FIG. 1 shows a schematic cross-section of a semiconductor device and of the corresponding package, coupled to a printed-circuit board;

FIGS. 2A-2C show schematic plan views regarding successive steps of a process for manufacturing the semiconductor device and the corresponding package, according to one embodiment of the present solution; and

FIG. 2D shows a perspective view of the semiconductor device and of the corresponding package, at the end of the manufacturing process.

### DETAILED DESCRIPTION

The present Applicant, through extensive tests and experimental evaluations, has realized that the use of a particular aluminum alloy as basic, constituent, material for providing the lead frame of the package of an integrated semiconductor device affords specific advantages that may not be obtained with commonly used materials.

In particular, this aluminum alloy envisages a content of silicon that ranges between 1% and 1.5%.

The present Applicant has further realized that an aluminum alloy that may advantageously be used for providing the lead frame is the one disclosed in WO 2013/037918 A1 (and US 2014/193666) which describes, however, the use of this material in a field that is altogether extraneous and unrelated to the field of manufacturing of integrated semiconductor devices, in particular in the automotive sector for formation of panels that constitute the vehicle. The use disclosed therein is for macro-applications, i.e., applications altogether different from an integratable solution, for example to produce panels of the body of the vehicle (e.g., for the bonnet or doors).

The aluminum alloy described in this document, identified by the code AA6016 by the manufacturer, Hydro Aluminium Rolled Products GmbH, is an aluminum and silicon alloy and further includes magnesium in a percentage comprised between 0.25% and 0.6%.

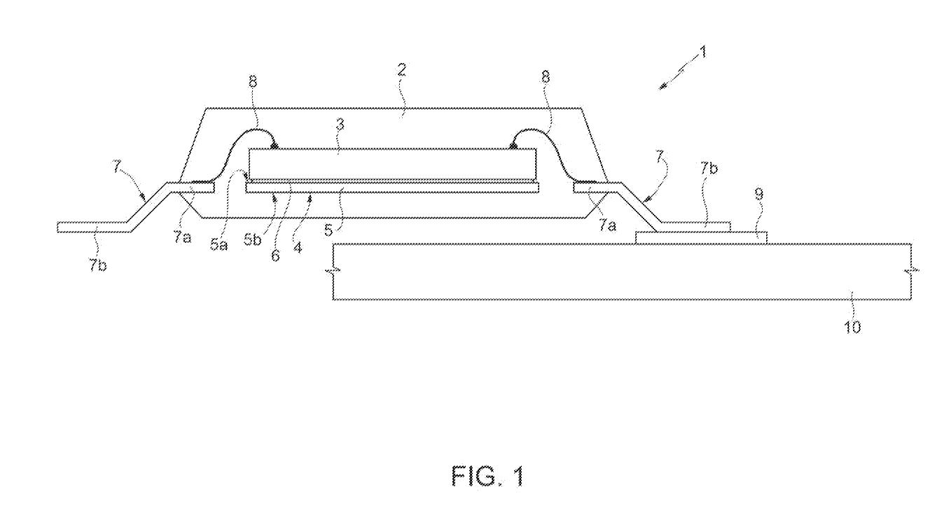

One aspect of the present solution consequently envisages use of an aluminum alloy with silicon content that ranges between 1% and 1.5%, for example the alloy described in the aforesaid document WO/2013 037918 A1, for the manufacturing of the lead frame of a semiconductor device, in particular a power semiconductor device (i.e., for applications on a microscopic scale). The semiconductor device may, for example, be made as described with reference to FIG. 1.

Lower percentages (for example, 0.1%-0.2%) of further metals, such as iron, manganese, chromium, tin, or zinc, or further dopant elements, such as phosphorus or beryllium, may be added to the aforesaid alloy, according to the particular applications; also, residual impurities may possibly be present.

The present Applicant has found that a lead frame of this type has optimized mechanical characteristics, for example in terms of strength and hardness, and electrical characteristics, for example avoiding the use of intermediate metal layers for electrical coupling with distinct materials, for example with electrical wires in the package, electrical pads carried by an external printed-circuit board, and/or the silicon die inside the package.

A further aspect of the present solution envisages an appropriate manufacturing process for production of a package of the semiconductor device.

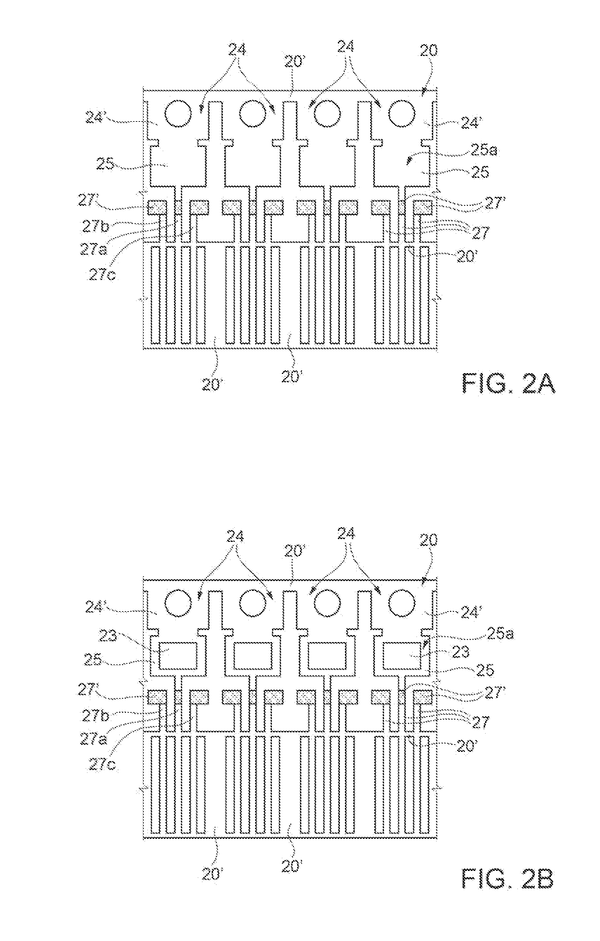

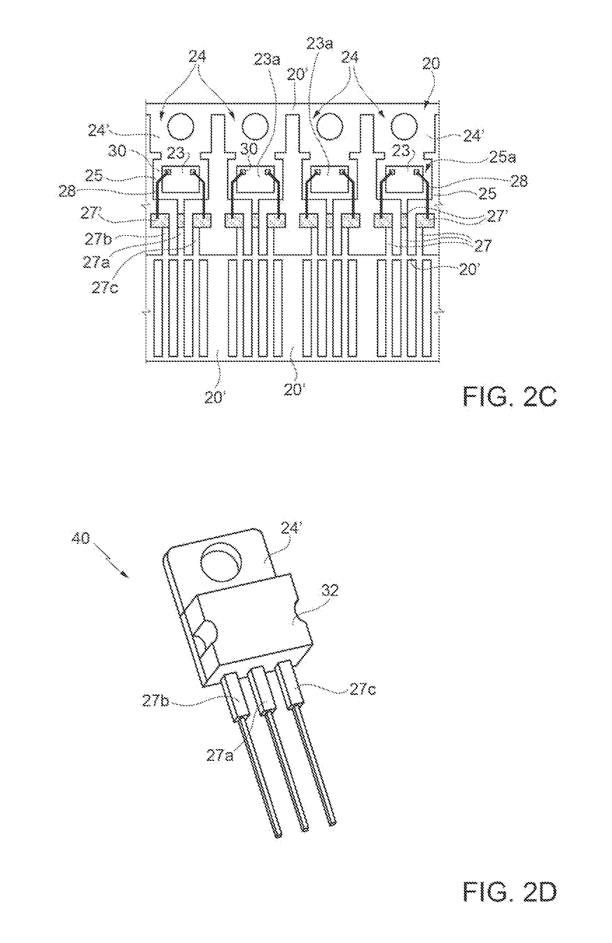

With initial reference to FIG. 2a, the manufacturing process envisages molding, with techniques of a known type and not described in detail herein, of a plate 20 of the aforesaid aluminum alloy comprising a silicon content that ranges between 1% and 1.5%, for definition of a plurality of lead frames 24, coupled together, at coupling regions 20′ of the plate 20 itself (for example, the various lead frames 24 may be arranged in rows or strips).

As mentioned previously, each lead frame 24 comprises: a support plate (in the following die paddle) 25, having a top surface 25a defining an area designed to receive a die of semiconductor material; and a plurality of leads 27, in the example three in number, of which a central lead 27a is integrally connected to the die paddle 25, and two side leads 27b, 27c are arranged laterally alongside the central lead 27a, connected thereto by respective coupling regions 20′.

In the example illustrated in FIG. 2a, the lead frame 24 further comprises a perforated external portion 24′, which is integrally connected to the die paddle 25 and is designed, in a way known and not described in detail herein, to be coupled to a heat dissipater.

In particular, each lead 27 has, in the proximity of the die paddle 25, at an area designed to be enclosed by a corresponding package, electrical connection regions 27′, designed for electrical connection with corresponding electrical bond wires.

The manufacturing process then proceeds (FIG. 2b) with coupling of a die 23 on the top surface 25a of the die paddle 25. The die 23 includes semiconductor material, for example silicon, and integrates one or more electronic components, for example one or more power MOSFET elements.

In particular, the aforesaid coupling may be obtained by bonding with a layer of adhesive material, arranged between the top surface 25a of the die paddle 25 and a bottom surface of the die 23 (in a way similar to what is illustrated in FIG. 1). In this case, no preliminary surface treatment of the die paddle 25 is envisaged.

Alternatively, the coupling may be obtained by soldering (the so-called “soft solder”), preferably a lead-free soldering.

In this case, an aspect of the present solution envisages a preliminary step of localized cleaning (the so-called “in situ cleaning”), in order to prepare the top surface 25a of the die paddle 25 for soldering to the die 23. This cleaning may, for example, remove impurities or oxides, or in general irregularities, that have formed on the top surface 25a.

The present Applicant has found that the cleaning operation further improves the wettability of the top surface 25a, thus facilitating the subsequent operation of coupling to the die 23.

For example, cleaning of the top surface 25a may be carried out with treatments of a physical (not chemical) type, such as localized laser or plasma treatment, in a per se known manner, as described, for example, in US 2008/0009129 A1, which is hereby incorporated by reference in whole.

Next, the manufacturing process envisages (FIG. 2c) electrical connection between the die 23 and the leads 27, with the wire-bonding technique (i.e., by connection with electrical wires).

Electrical bond wires 28 are thus connected between the electrical connection regions 27′ of the leads 27 (in particular the side leads 27b, 27c) and contact pads 30 carried by a top surface 23a of the die 23, not in contact with the die paddle 25.

In particular, the electrical connection may be obtained with ultrasound bonding techniques (of a type known and not described in detail herein), in case aluminum electrical bond wires 28 are used. In this case, no preliminary surface treatment of the leads 27 is envisaged.

Alternatively, in the case of use of electrical bond wires 28 of copper, gold, or silver, a thermosonic bonding technique may be used (of a known type, not described in detail herein).

In this case, one aspect of the present solution envisages a preliminary step of in situ cleaning in order to prepare the top surface 23a of the die 23, at the area of the contact pads 30 and the electrical connection regions 27′ of the leads 27.

Cleaning may, for example, remove impurities or oxides, or in general irregularities, and may be carried out by localized laser or plasma treatment.

The manufacturing process then proceeds (see FIG. 2d) with formation of the package 32, of plastic material, for example epoxy resin, with molding techniques, for example injection molding (of a known type, not described in detail herein). The material of the package 32 coats, in particular, the die 23 and the die paddle 25, the electrical bond wires 28 and the electrical connection regions 27′ of the leads 27. This step does not envisage any operation of treatment or machining of the lead frame 24.

Furthermore, the so-called “cropping” operation is carried out at the coupling regions 20′, to separate the various lead frames 24 from one another and further the leads 27 of each lead frame 24, in order to obtain individual semiconductor devices 40, for example power-transistor devices (as illustrated in the aforesaid FIG. 2d). Also this step does not envisage any operation of treatment or machining of the lead frame 24.

The manufacturing process terminate with an operation of surface finishing of the termination portions of the leads 27, external to the package 32 (the so-called “solder dipping” operation).

In particular, the aforesaid external termination portions of the leads 27 are coated with a solder coating, with or without lead, designed to facilitate future operations of soldering, for example to a printed-circuit board (not illustrated herein).

The solder coating may, for example, be applied by successive steps of: dipping of the external terminations of the leads 27 in a flux, which also enables removal of possible surface oxides; dipping of the same terminations in a molten solder material, at a temperature, for example, comprised between 250° C. and 300° C.; and final washing, for example with water.

The advantages of the solution proposed emerge clearly from the foregoing description.

In any case, it is emphasized that this solution allows to avoid the need to use intermediate layers on the lead frame, for example metal layers, which are in general formed by electrodeposition in order to enable electrical coupling thereof.

In fact, the manufacturing process envisages in this case at most preliminary operations of in situ cleaning, aimed at improving the characteristics of electrical coupling of the lead frames (in particular, of the corresponding die paddle and of the corresponding leads).

Further, the aluminum alloy used for providing the lead frame enables desired mechanical characteristics to be achieved, for example, in terms of strength, thus enabling desired characteristics of machinability of the resulting lead frame. The present Applicant has, for example, found a stiffness of the lead frame comprised between 60 and 80 Brinell, i.e., much higher as compared to the results obtained using traditional materials.

The above advantages, in particular in terms of strength and absence of steps of electrodeposition of intermediate coupling layers are particularly evident, for example, if compared to the solution of the above cited US 2013/0221507 A1.

Furthermore, the material indicated in the present solution is easy to process by molding and thus does not entail modifications to already existing machines.

Finally, it is clear that modifications and variations may be made to what has been described and illustrated herein, without thereby departing from the scope of the present disclosure.

In particular, it is evident that the solution described finds advantageous application for any semiconductor device (even not of the power type) that includes a package provided with lead frames.

Further, it is evident that the particular conformation of the lead frame and of the package may differ from the one described with reference to FIGS. 2a-2d. For example, the resulting semiconductor device 40 may comprise a different number of leads 27, or be without the external portion 24′ of the lead frame 24 for coupling to a dissipater.

In addition, as it has been highlighted previously, the aluminum alloy, including silicon in the percentages indicated, may possibly comprise further constituent elements, for example dopant elements in low percentages (for example, 0.2%-0.3%).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor device, comprising:
a die including semiconductor material;
a lead frame having a support plate supporting said die and leads electrically coupled to said die, wherein the lead frame is an aluminum alloy including a percentage of silicon that is between 1% and 1.5%; and
a package that includes encapsulating material encapsulating said die, wherein a portion of said leads protrude from the package.

2. The device according to claim 1, comprising at least one electrical bonding wire within said package directly coupled to a first end of at least one of said leads and a second end coupled to a contact pad of said die.

3. The device according to claim 1, wherein:
the portions of said leads protrude from said package are configured to be directly coupled with contact pads of another device or board.

4. The device according to claim 1, wherein said die is directly coupled to a surface of the support plate of the lead frame.

5. The device according to claim 1, wherein said die is coupled to a surface of the support plate of the lead frame by an adhesive.

6. The device according to claim 1, wherein said aluminum alloy further includes a percentage of magnesium between 0.25% and 0.6%.

7. The device according to claim 1, wherein said semiconductor device is a power device.

8. A process for manufacturing a semiconductor device, the comprising:
coupling a semiconductor die to a support plate of a lead frame that includes an aluminum alloy, the aluminum alloy including a pertentage of silicon that is between 1% and 1.5%, the lead frame including a lead; and
forming a package that includes encapsulating material to encapsulate said die, wherein a portion of the lead protrudes from the package.

9. The process according to claim 8, further comprising
electrically coupling a first end of a bonding wire directly to a first end of the lead; and
electrically coupling a second end of the bonding wire to a contact pad of said die.

10. The process according to claim 8, further comprising directly coupling the portion of the protruding from the package to a contact pad of another device or board.

11. The process according to claim 8, wherein coupling the die to the support plate comprises soldering a back surface of the die to an upper surface of the support plate.

12. The process according to claim 9, further comprising, prior to coupling the die to the support plate, cleaning of said lead frame.

13. The process according to claim 8, wherein said aluminum alloy further comprises a percentage of magnesium ranging between 0.25% and 0.6%.

15. The process according to claim 8, wherein said semiconductor device is a power device.

16. A package comprising:
a lead frame that includes a die pad and a lead, the leadframe being an aluminum alloy that contains between 1% to 1.5% silicon;
a semiconductor die coupled to a surface of the die pad;
a conductive wire electrically coupling a bond pad of the semiconductor die to a first portion of the of lead; and
a package encapsulating the die and the conductive wire, a second portion of the lead extending form the package.

17. The packge of claim 16, wherein remaining portions of the aluminum alloy are aluminum.

18. The package of claim 16, wherein the aluminum alloy contains a percentage of magnesium ranging between 0.25% and 0.6%.

19. The package of claim 16, wherein the lead is a first lead, the package further including a second lead having a first portion in the package and second portion that extends from the die pad.

20. The package of claim 16, wherein the second portion of the lead is configured to be directly coupled to a contact pad of another device or a substrate.

21. The package of claim 16, wherein the package is a power device.
